(19) United States
(12) Patent Application Publication
(10) Pub. No.: US 2007/0164386 A1
(43) Pub. Date: Jul. 19, 2007

(54) Semiconductor device and fabrication method thereof

(75) Inventors: Cheng-Yi Chang, Taichung Hsien (TW); Chien-Ping Huang, Hsinchu Hsien (TW); Yu-Po Wang, Taichung Hsien (TW); Chih-Ming Huang, Hsinchu Hsien (TW); Cheng-Hsu Hsiao, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/648,045

(22) Filed: Dec. 28, 2006

(30) Foreign Application Priority Data
Jan. 18, 2006 (TW) 095101836

(51) Int. Cl. H01L 31/0203; H01L 21/56

(52) U.S. Cl. 257/434; 438/116; 438/67; 438/617; 257/784; 257/680

(57) ABSTRACT

A semiconductor device and the fabrication method thereof are provided. The fabrication method includes providing a substrate module plate having a plurality of substrates; attaching at least one sensor chip to each of the substrates of the substrate module plate; electrically connecting each of the sensor chips to each of the substrates through bonding wires; forming an insulating layer between each sensor chip on the substrate module plate, wherein the height of the insulating layers are not greater than the thickness of the sensor chips so as to prevent flash from the insulating layers from contaminating the sensor chips; forming an adhesive lip on the insulating layer or forming a second insulating layer followed by forming the adhesive layer, wherein the adhesive layer or the second insulating layer is higher than the highest loop-height of the bonding wires; adhering a light transmitting cover to each adhesive layer to cover the sensor chip; and cutting the substrate module plate to separate the substrates to form a plurality of semiconductor devices each integrated with at least one sensor chip. As the adhesive layers are not in contact with the bonding wires, the problems of damaging or breaking the bonding wires can be prevented in the process of adhering the light transmitting cover.

### BACKGROUND OF THE INVENTION

1. Field of the Invention

The present invention relates generally to semiconductor devices and fabrication methods thereof, and more particularly to a sensor semiconductor device and the fabrication method thereof.

2. Description of Related Art

In a conventional image sensor package, a sensor chip is mounted to a chip carrier and electrically connected to the chip carrier through bonding wires. The upper surface of the sensor chip is further covered by a glass plate for allowing image light to be captured by the sensor chip. Thus, the completed image sensor package is ready to be integrated into external devices such as printed circuit boards to be applied to various kinds of electronic products, such as digital cameras, digital videos, optical mice, mobile phones, fingerprint readers and so on.

FIG. 1 shows a sensor package disclosed by U.S. Pat. No. 6,060,340. A prepared dam structure 13 is mounted to a substrate 11 through an adhesive 16, the dam structure 13 being a wall structure surrounding a space 14 to accommodate a sensor chip 10 and bonding wires 12 in the space 14, the bonding wires 12 electrically connecting the sensor chip 10 to the substrate 11. A glass cover 15 is adhered to the dam structure 13 for covering the space 14, so as to isolate the sensor chip 10 and bonding wires 12 from ambient air while allowing external light to transmit and reach the sensor chip 10 for the operation of the sensor chip 10. However, the adhesive 16 has a relatively high moisture absorption, such that when an adhesive containing water vapor has undergone the subsequent processes in environments of high temperature, the dam structure is liable to a popcorn phenomenon and even delamination occurring between the substrate and the dam structure, thereby adversely affecting the package reliability.

FIGS. 2A and 2B show other types of sensor packages free of adhesives that are respectively disclosed by U.S. Pat. No. 6,262,479 and U.S. Pat. No. 6,590,269. Referring to FIG. 2A, instead of using the above-described adhesive, a packaging mold having an upper mold 27 and a lower mold 28 is used to perform a molding process so as to form a dam structure 23 on the substrate 21. Therein, the upper mold 27 has an upper mold cavity 270 in which the dam structure 23 will be formed to encompass an area for the sensor chip, wherein a protruding portion 271 extends downward into the sensor chip area in the center of the upper mold cavity 270. The substrate 21 is disposed between the upper mold 27 and the lower mold 28, and the protruding portion 271 is in contact with the substrate 21 and thus covers a predefined area where the sensor chip is to be mounted and the bonding wires are to be formed. Then, a resin compound such as epoxy resin compound is injected to the upper mold cavity 270 to form the dam structure 23 on the substrate 21. Because of the protruding portion 271, the predefined area on the substrate 21 for mounting the sensor chip and bonding wires will not be covered by the dam structure 23. Instead, the predefined area on the substrate 21 will be exposed from the dam structure after the upper and lower molds 27, 28 are removed from the substrate 21. As shown in FIG. 2B, the sensor chip 20 and the bonding wires 22 are mounted to the exposed area of the substrate 21 and then a glass cover 25 is adhered to the dam structure 23, thus forming a sensor package.

However, the above package is inherent with some drawbacks, such as the difficulty in controlling the clamping force between the protruding portion and the substrate. If the protruding portion cannot be stably disposed on the substrate, the resin compound can easily flash between the protruding portion and the substrate and thus contaminate the area for mounting the chip and bonding wires. On the other hand, the substrate may be easily damaged if the clamping force between the protruding portion and the substrate is excessive. In addition, the cost of fabricating such a mold with a protruding portion is high, and also any change of size in the substrate or the predefined area will necessitate production of a new mold thereby substantially increasing the fabrication cost and complicating the fabrication process.

Accordingly, U.S. Pat. No. 5,950,074 discloses another kind of sensor package, wherein a fluid adhesive is coated on the substrate to form a dam structure for a glass cover to adhere thereto to further cover the sensor chip and bonding wires disposed in the dam structure.

However, there exists a common problem in the above-described packages: the planar size of the packages comprises the chip size, the wire bonding space, and the space for the dam structure, which collectively occupy a relatively large space, particularly the area that has to be reserved for disposing the dam structure, thus such packages fail to meet the demands for miniaturized packages.

Referring to FIG. 3, a sensor package having a reduced size is disclosed by U.S. Pat. No. 5,962,810. A sensor chip 30 having a sensor area on an active surface thereof is mounted on a substrate 31. The sensor chip 30 and the substrate 31 are electrically connected through bonding wires 32. Then, a fluid adhesive 33 is coated on the bonding wires 32 to form a dam structure that extends to the circumference of the sensor chip 30 to completely encapsulate the bonding wires 32. Then, a transparent adhesive 35 is coated on the sensor chip 30 to form a sensor package having reduced size.

Further referring to FIG. 4, a similar structure is disclosed by Taiwan patent No. 174268. A sensor chip 40 having a sensor area on an active surface thereof is mounted to a substrate 41. The sensor chip 40 and the substrate 41 are electrically connected through bonding wires 42. Then, an adhesive 43 is coated on the bonding wires 42 around the sensor chip 40 to form a dam structure. The height of the adhesive 43 is larger than the thickness of the sensor chip 40. Subsequently, a light-transmitting layer 45 is adhered to the adhesive 43 by the adhesion characteristic thereof. In the prior art, the adhesive coated on the bonding wires is required to function as a wall and an adhesive at the same time for a light transmitting layer to be mounted thereon. The adhesive should possess a required degree of rigidity, which is generally accomplished by adding some fillers in the adhesive so as to form a dam structure, but this reduces-the adhesion force between the adhesive and the light transmitting layer. However, if the amount of the filler is reduced in order to increase the adhesion force between the adhesive and the light transmitting layer, the rigidity of the dam structure will be reduced, potentially causing a leakage problem of the light transmitting layer and thus affecting product reliability.

Furthermore, in the process of adhering the light transmitting layer to the adhesive encapsulated with the bonding wires, it is necessary to adhere the light transmitting layer to the adhesive before the adhesive is completely cured, but this can easily cause damage or break of the bonding wires.

Moreover, in the process of coating the adhesive, because the adhesive encapsulates the bonding wires and the height of the adhesive is larger than the thickness of the sensor chip, the adhesive easily flashes, contaminating the active surface of the sensor chip, resulting in unserviceable items that must be scrapped.

Therefore, it is desirable to develop an improved sensor package device and a fabrication method thereof which can provide a strong dam structure without having to reduce the adhesion between the dam structure and the light transmitting layer, and, meanwhile, prevent the problems of leakage in the light transmitting layer, breaking of the bonding wires,.and contamination of the sensor chip due to flash.

### SUMMARY OF THE INVENTION

In view of the above drawbacks, an objective of the present invention is to provide a sensor semiconductor device and the fabrication method thereof that has a miniaturized profile.

Another objective of the present invention is to provide a sensor semiconductor device and the fabrication method thereof, in which the rigidity of the dam structure is strengthened while maintaining the adhesion force between the dam structure and the light transmitting layer.

A further objective of the present invention is to provide a sensor semiconductor device and the fabrication method thereof, which maintain good adhesion between the dam structure and the light transmitting layer without causing the leakage problem.

Still another objective of the present invention is to provide a sensor semiconductor device and the fabrication method thereof, which can prevent the problems of damaging or breaking the bonding wires in the process of adhering the light transmitting layer to the dam structure.

A further objective of the present invention is to provide a sensor semiconductor device and the fabrication method thereof, which can prevent the sensor area in the sensor chip from contamination in the process of forming the dam structure.

In order to attain the above and other objectives, a fabrication method of a semiconductor device is provided comprising the steps of: providing a substrate module plate having a plurality of substrates and attaching at least one sensor chip to each of the substrates of the substrate module plate, wherein each of the sensor chips has an active surface with a sensor area and a non-active surface opposed to the active surface, the sensor chips being attached to the substrates through the non-active surfaces thereof; electrically connecting the active surface of each sensor chip to each of the substrates through bonding wires; forming an insulating layer between each of the sensor chips on the substrate module plate, wherein the height of the insulating layer is not greater than the thickness of the sensor chip; forming an adhesive layer on the insulating layer, wherein the height of the adhesive layer is greater than the highest loop-height of the bonding wires; adhering a light transmitting cover to each of the adhesive layers; and cutting the substrate module plate to form a plurality of individual semiconductor devices each having a light transmitting cover and a sensor chip formed thereon. The present invention also discloses a semiconductor device, comprising: a substrate; a sensor chip attached to the substrate, wherein the planar size of the sensor chip is smaller than that of the substrate, the sensor chip having an active surface with a sensor area and a non-active surface opposed to the active surface, the sensor chip being attached to the substrate via its non-active surface; a plurality of bonding wires for electrically connecting the sensor chip to the substrate; an insulating layer for covering the area not attached with sensor chip on the substrate, wherein the height of the insulating layer is not greater than the thickness of the sensor chip; an adhesive layer formed on the insulating layer, the height of the adhesive layer being greater than the loop-height of the bonding wires; and a light transmitting cover adhered to the adhesive layer and covering the sensor chip. Therein, the adhesive layer is not in contact with the bonding wires so as to avoid the problems of damaging or breaking the bonding wires.

Further, according to another embodiment of the present invention, a second insulating layer can be formed on the insulating layer surrounding the sensor chip, and the second insulating layer is higher than the highest loop-height of the bonding wires. Then, the adhesive layer is formed on the second insulating layer and the light transmitting cover is adhered to the adhesive layer and covers the sensor chip.

In summary, the semiconductor devices and fabrication method thereof according to the present invention mainly comprise the steps of providing a substrate module plate having a plurality of substrates; attaching at least one sensor chip to each of the substrates of the substrate module plate; electrically connecting each of the sensor chips to each of the substrates through bonding wires; forming an insulating layer between each sensor chip on the substrate module plate, wherein the height of the insulating layer is not greater than the thickness of the sensor chip and the insulating layer is formed with the dam structure holding the sensor chip, thereby preventing the insulating layer from flashing and contaminating the sensor chip; forming an adhesive layer on the insulating layer or forming a second insulating layer after the formation of the adhesive layer, wherein the adhesive layer or the second insulating layer is higher than the highest loop-height of the bonding wires; adhering a light transmitting cover to the adhesive layer to cover the sensor chip; and cutting the substrate module plate to separate the plurality of substrates to form individual semiconductor devices each integrated with at least one sensor chip. As the adhesive layer is not in contact with the bonding wires, the problem of damaging or breaking the bonding wires can be prevented in the process of adhering the light transmitting cover to the adhesive layer. In addition, because the insulating layer that serves as the dam structure and the adhesive layer for attaching the light transmitting cover are made of different materials, the prior the problems of weak dam structures formed by a single adhesive and leakage in the light transmitting cover can be prevented. Meanwhile, the light transmitting cover can be securely affixed to the insulating layer to serve as a dam structure through the adhesive layer of the present invention, thereby increasing reliability in the fabrication process. Moreover, as the insulating layer and the dam structure are closely attached to the periphery of the sensor chip, the size of the whole semiconductor device can be desirably reduced

### BRIEF DESCRIPTION OF DRAWINGS

FIGS. 1 is a cross-sectional diagram of a sensor package disclosed by U.S. Pat. No. 6,060,340;

FIGS. 2A and 2B are cross-sectional diagrams of sensor packages disclosed by U.S. Pat. No. 6,262,479 and U.S. Pat. No. 6,590,269, respectively;

FIG. 3 is a cross-sectional diagram of a sensor package disclosed by U.S. Pat. No. 5,962,810;

FIG. 4 is a cross-sectional diagram of a sensor package disclosed by Taiwan patent No. 174268;

FIGS. 5A to 5D are cross-sectional diagrams showing a method of fabricating semiconductor devices according to a first embodiment of the present invention;

FIGS. 6A to 6D are. cross-sectional diagrams showing a method of fabricating semiconductor devices according to a second embodiment of the present invention; and

FIG. 7 is a cross-sectional diagram of semiconductor devices according to a third embodiment of the present invention.

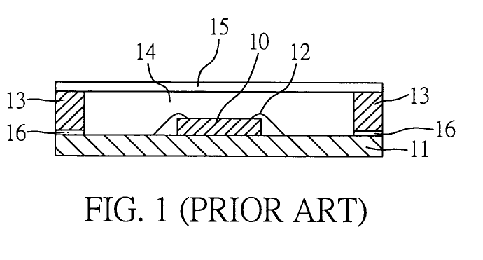

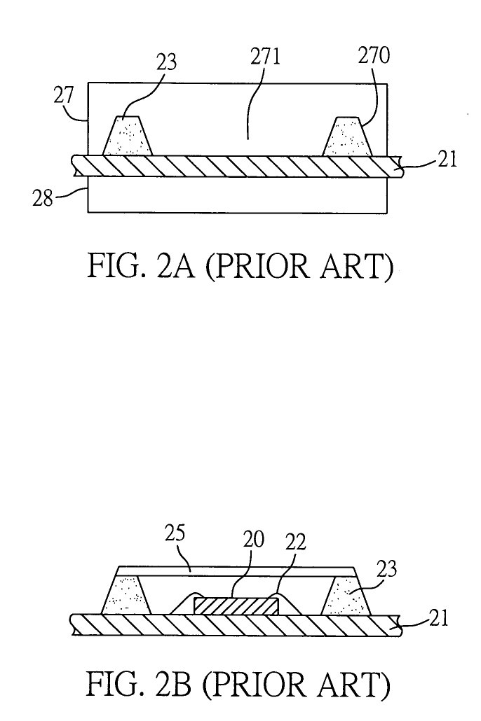

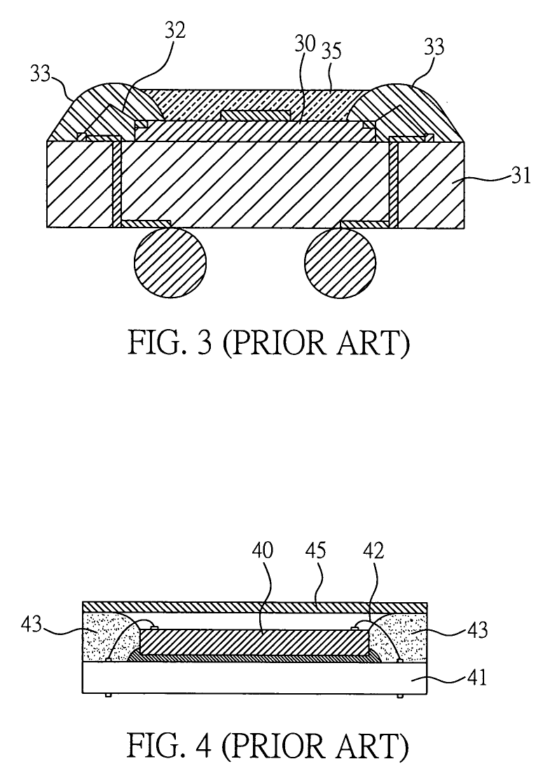

### DETAILED DESCRIPTION OF PREFERRED EMBODIMENTS

The following illustrative embodiments are provided to illustrate the disclosure of the present invention; these and other advantages and effects will be apparent to those skilled in the art after reading the disclosure of this specification. The present invention can also be performed or applied by other, differing, embodiments. The details of the specification may be changed on the basis of different points and applications, and numerous modifications and variations can be made without departing from the spirit of the present invention.

### First Embodiment

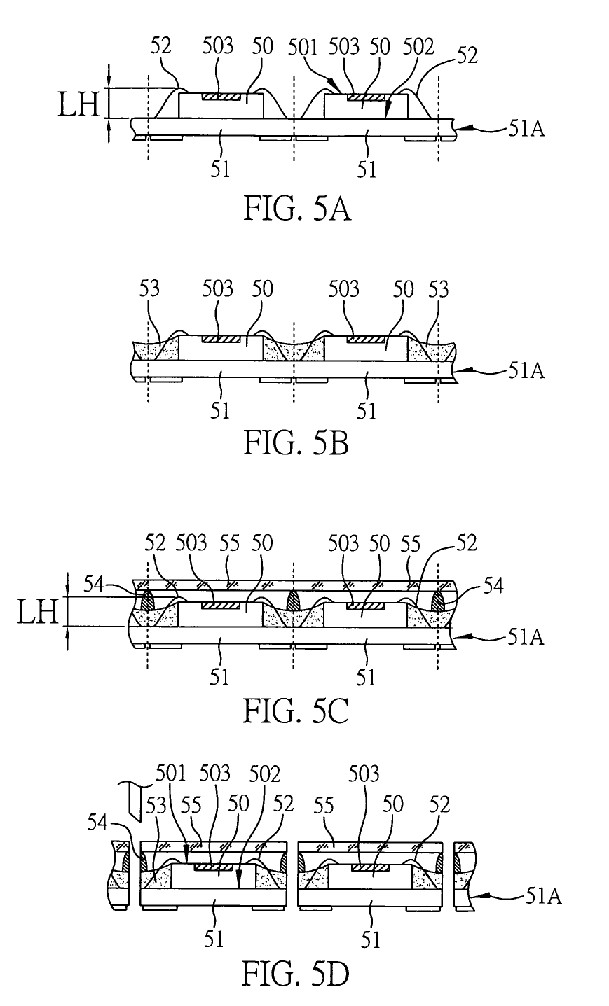

FIGS. 5A to 5D are cross-sectional diagrams showing a method of fabricating a semiconductor device according to a first embodiment of the present invention. In the present embodiment, multiple semiconductor devices are fabricated in batches during mass production. Of course, the semiconductor devices may also be individually fabricated according to the requirements of the practical fabrication process.

As shown in FIG. 5A, a substrate module plate 51A having a plurality of substrates 51 is provided and at least one sensor chip 50 is attached to each of the substrates 51 of the substrate module plate 51A, wherein the planar size of each sensor chip 50 is smaller than that of each substrate 51. The substrate module plate 51A may be arranged in matrix or strip. Each of the sensor chips 50 has an active surface 501 with a sensor area 503 and a non-active surface 502 opposed to the active surface 501. The sensor chips 50 are attached to the substrates 51 by the non-active surfaces 502 thereof, and electrically connected to the substrates 51 through bonding wires 52. Also, the non-active surfaces 502 of the sensor chips 50 may be thinned before being attached to the substrates 51.

As shown in FIG. 5B, insulating layers 53 are formed in each gap between the sensor chips 50 on the substrate module plate 51A. The height of the insulating layers 53 is not greater than the thickness of the sensor chips 50. The insulating layers 53 may be made of resin compound such as epoxy resin compound. The insulating layers 53 are formed in the gaps between the sensor chips 50 on the substrate module plate 51A and then cured to form dam structures for efficiently holding each sensor chip 50.

As shown in FIG. 5C, adhesive layers 54 are formed on the insulating layers 53, wherein each of the adhesive layers 54 is higher than the highest loop-height(LH) of the bonding wires 52. Further, a light transmitting cover 55 is adhered to the adhesive layers 54 for allowing external light to transmit therethrough and reach the sensor areas 503 of the sensor chips 50, thereby enabling the sensor chips 50 to operate. In the present embodiment, the adhesive layers 54 are made detached from the bonding wires 52 to prevent the problems of damaging or cracking the bonding wires 52 in the process of adhering the light transmitting covers 55 to the adhesive layers 54. The adhesive layers 54 may be made of an UV adhesive, and the light transmitting covers 55 may be made of glass. While adhering the light transmitting covers 55 to the adhesive layers 54 made of a UV adhesive, the UV light is irradiated on the adhesive layers 54 to initiate curing of the UV adhesive, thereby efficiently fixing the light transmitting covers 55 on the adhesive layers 54.

As shown in FIG. 5D, the substrate module plate 51A is cut along the predetermined lines separating each of the substrates 51, and cut through the insulating layers 53 and the adhesive layers 54 to form a plurality of semiconductor devices each having a light transmitting cover and a sensor chip formed thereon. As the insulating layers 53 that serve as dam structures are closely attached to the periphery of the sensor chips, the size of the whole semiconductor devices can be noticeably reduced to meet the miniaturization trend in the electronic industry.

Through the above fabrication method, the present invention also discloses a semiconductor device comprising: a substrate 51; a sensor chip 50 attached to the substrate 51, wherein the planar size of the sensor chip 50 is smaller than that of the substrate 51, the sensor chip 50 having an active surface 501 with a sensor area 503 and a non-active surface 502 opposite the active surface 501, the sensor chip 50 being attached to the substrate 51 through its non-active surface 502; a plurality of bonding wires 52 for electrically connecting the sensor chip 50 to the substrate 51; an insulating layer 53 for covering the area not attached with the sensor chip 50 of the substrate 51, wherein the height of the insulating layer 53 is not greater than the thickness of the sensor chip 50; an adhesive layer 54 formed on the insulating layer 53, wherein the adhesive layer is higher than the highest loop-height of the bonding wires 52; and a light transmitting cover 55 adhered to the adhesive layer 54 and covering the sensor chip 50.

In the semiconductor device and the fabrication method of the present invention, the height of the insulating layer is not greater than the thickness of the sensor chip. As a result, when the insulating layer that serves as a dam structure is formed to surround the sensor chip, the sensor area of the sensor chip is prevented from being contaminated by flash of the insulating layer. Further, as the adhesive layer is not in contact with the bonding wires, the problems of damaging or breaking the bonding wires can be avoided in the process of adhering the light transmitting cover to the adhesive layer. Furthermore, since the dam structure formed by the insulating layer and the adhesive layer for attachment of the light transmitting cover are made of different materials, the problems of a weak dam structure made by a single adhesive in the prior art and leakage in the light transmitting cover can be solved, and also the light transmitting cover can be efficiently fixed onto the insulating layer through the adhesive layer, thereby increasing the process reliability.

### Second Embodiment

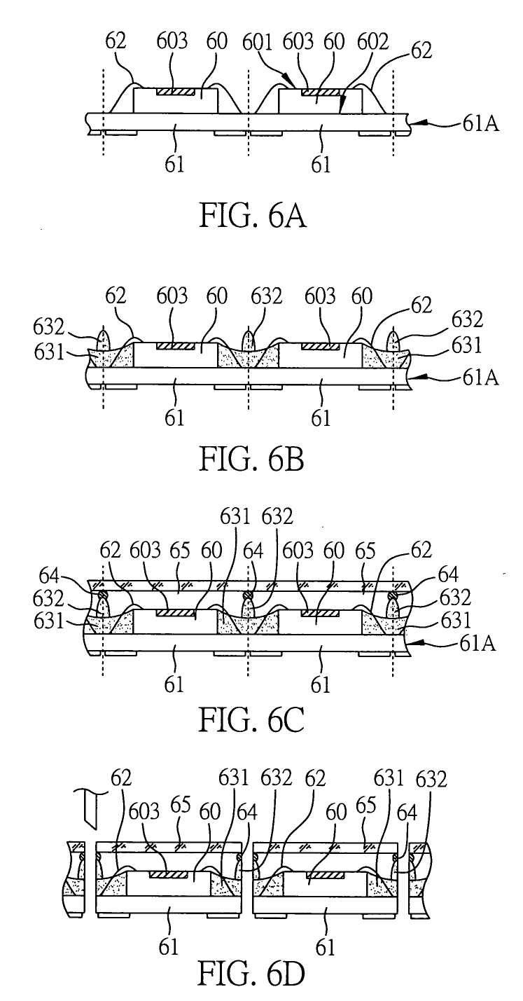

FIGS. 6A to 6D are cross-sectional diagrams showing a fabrication method of a semiconductor device according to a second embodiment of the present invention. In this embodiment, the semiconductor device is fabricated by a similar method to the foregoing and only differs in that a second insulating layer is further formed on the insulating layer and then the adhesive layer is formed on the second insulating layer for the light transmitting cover to be attached thereon.

As shown in FIG. 6A, a substrate module plate 61A having a plurality of substrates 61 is provided and at least one sensor chip 60 is attached to each of the substrates 61 of the substrate module plate 61A. The planar size of each sensor chip 60 is smaller than that of each substrate 61. The substrate module plate 61A may be arranged in matrix or strip. Each of the sensor chips 60 has an active surface 601 with a sensor area 603 and a non-active surface 602 opposed to the active surface 601. The sensor chips 60 are attached to the substrates 61 by the non-active surfaces 602 thereof, and electrically connected to the substrates 61 through bonding wires 62. The non-active surfaces 602 of the sensor chips 60 may be thinned before being attached to the substrates 61.

As shown in FIG. 6B, first insulating layers 631 are formed in the gaps between each of the sensor chips 60 on the substrate module plate 61A. The height of the first insulating layers 631 is not greater than the thickness of the sensor chips 60. The first insulating layers 631 may be made of resin compound such as epoxy resin compound, which is formed in the gaps between each of the sensor chips 60 on the substrate module plate 61A. Furthermore, second insulating layers 632 are formed on the first insulating layers 631. Each second insulating layer 632 is higher than the highest loop-height of the bonding wires 62. The first and second insulating layers 631, 632 may be made of the same or different materials. The first and second insulating layers 631, 632 are cured so as to form dam structures for efficiently holding the sensor chips 60.

As shown in FIG. 6C, adhesive layers 64 are formed of adhesive material on the second insulating layers 632 and a light transmitting cover 65 is further adhered to each of the adhesive layers 632 for covering the sensor chips 60, allowing external light to transmit through the light transmitting cover 65 and reach the sensor areas 603 of the sensor chips 60 to enable the sensor chips 60 to operate. The bonding wires 62 can be exposed from the second insulating layer 632 without being in contact with the adhesive layers 64, thereby preventing the problems of breaking or damaging the bonding wires 62 in the process of adhering the light transmitting cover 65 onto the adhesive layers 64. The adhesive layers 64 may be made of a UV-curable adhesive, and the light transmitting covers 65 may be made of glass. While adhering the light transmitting cover 65 to the adhesive layers 64 made of such as a UV-curable adhesive, the UV light is irradiated on the adhesive layers 64 to initiate curing of the UV adhesive, thereby efficiently fixing the light transmitting covers 65 onto the adhesive layers 64.

As shown in FIG. 6D, the substrate module plate 61A is cut along the predetermined lines for forming each substrate 61 and meanwhile cut through the first insulating layers 631, the second insulating layers 632, and the adhesive layers 64 so as to form a plurality of separate semiconductor devices each having a light transmitting cover and a sensor chip formed thereon.

### Third Embodiment

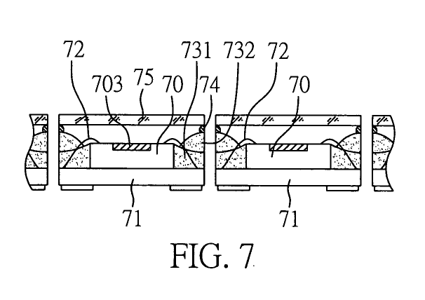

FIG.7 is a cross-sectional diagram showing a semiconductor device according to a third embodiment of the present invention. The fabrication method of the present embodiment is substantially the same as that of the second embodiment and only differs in that the second insulating layers 732 can be made to cover the bonding wires 72. In order to prevent the sensor areas 703 of the sensor chips 70 from being contaminated by flash of the second insulating layers 732, the second insulating layers 732 do not extend to cover the sensor chips 70.

Therefore, the semiconductor devices and the fabrication methods thereof of the present invention mainly comprise providing a substrate module plate having a plurality of substrates; attaching at least one sensor chip to each of the substrates of the substrate module plate; electrically connecting each of the sensor chips to each of the substrates through bonding wires; forming insulating layers in the gaps between each of the sensor chips on the substrate module plate, wherein the height of the insulating layers is not greater than the thickness of the sensor chips, and wherein the insulating layers serve as dam structures for securely holding the sensor chips to prevent flash of the insulating layers from contaminating the sensor chips; forming adhesive layers on the insulating layers or forming second insulating layers followed by forming adhesive layers, wherein each adhesive layer or each second insulating layer is higher than the highest loop-height of the bonding wires; adhering a light transmitting cover to the adhesive layer to cover the sensor chip; and cutting the substrate module plate to separate the plurality of substrates so as to form a plurality of semiconductor devices each integrated with at least one sensor chip. As the adhesive layers are not in contact with the bonding wires, the problems of damaging or breaking the bonding wires can be prevented in the process of adhering the light transmitting cover onto the adhesive layers. In addition, because the dam structure formed by the insulating layer and the adhesive layers for adhering the light transmitting cover thereto are made of different materials, the problems of having a weak dam structure formed by a single adhesive as in the prior art and the leakage of the light transmitting cover can be prevented. Meanwhile, the light transmitting cover can be efficiently fixed to the insulating layers that serve as the dam structure through the adhesive layer of the present invention, thereby increasing process reliability. Moreover, as the dam structure formed by the insulating layer is closely attached to the periphery of the sensor chip, the size of the whole semiconductor devices can be significantly reduced.

The above-described descriptions of the detailed embodiments are only intended to illustrate the preferred implementations according to the present invention but not to limit the scope of the present invention. Accordingly, various modifications and variations made by those having ordinary skill in the art can be made that fall within the scope of present invention as defined by the appended claims.

What is claimed is:

1. A method for fabricating semiconductor devices, comprising the steps of:
providing a substrate module plate having a plurality of substrates and attaching at least one sensor chip to each of the substrates of the substrate module plate, wherein each sensor chip has an active surface with a sensor area and a non-active surface opposite the active surface, the sensor chips being attached to the substrates through the non-active surfaces thereof;
electrically connecting the active surface of each of the sensor chips to each of the substrates through bonding wires;
forming insulating layers in gaps between the sensor chips on the substrate module plate, wherein the height of the insulating layers is not greater than the thickness of the sensor chips;
forming adhesive layers on the insulating layers, wherein each adhesive layer is higher than the highest loop-height of the bonding wires;
adhering a light transmitting cover to each of the adhesive layers; and
cutting the substrate module plate so as to form a plurality of semiconductor devices each having a light transmitting cover and a sensor chip formed thereon.

2. The fabrication method of claim 1, wherein the non-active surface of the sensor chip is thinned before being attached to the substrate.

3. The fabrication method of claim 1, wherein the insulating layers are made of resin compound, the resin compound being formed in the gaps between the sensor chips on the substrate module plate and then cured so as to form the dam structures for efficiently holding the sensor chips.

4. The fabrication method of claim 1, wherein the adhesive layers are not in contact with the bonding wires.

5. The fabrication method of claim 1, wherein the adhesive layers are made of a UV-curable adhesive which can be cured by UV light irradiated on the adhesive layers while adhering the light transmitting cover to the adhesive layers, thereby fixing the light transmitting cover to the adhesive layers.

6. The fabrication method of claim 1, wherein while cutting along the edges of the substrates, the insulating layers and adhesive layers are also cut.

7. The fabrication method of claim 1, wherein second insulating layers are formed on the insulating layers and then the adhesive layers are formed on the second insulating layers for the light transmitting cover to be attached thereon.

8. The fabrication method of claim 7, wherein the second insulating layers are higher than the highest loop-height of the bonding wires.

9. The fabrication method of claim 8, wherein while cutting along the edges of the substrates, the insulating layers, the second insulating layers, and adhesive layers are also cut.

10. The fabrication method of claim 8, wherein the second insulating layers can be made to cover the bonding wires or detach from the bonding wires.

11. A semiconductor device, comprising:
a substrate;
a sensor chip attached to the substrate, wherein the planar size of the sensor chip is smaller than that of the substrate, and the sensor chip has an active surface with a sensor area and a non-active surface opposite the active surface, the sensor chip being attached to the substrate through its non-active surface;
a plurality of bonding wires for electrically connecting the sensor chip to the substrate;
an insulating layer covering the area of the substrate not attached with the sensor chip, wherein the height of the insulating layer is not greater than the thickness of the sensor chip;
an adhesive layer formed on the insulating layer, the height of the adhesive layer being no greater than the highest loop-height of the bonding wires; and
a light transmitting cover adhered to the adhesive layer and covering the sensor chip.

12. The semiconductor device of claim 11, wherein the non-active surface of the sensor chip is thinned.

13. The semiconductor device of claim 11, wherein the insulating layer is made of resin compound, the resin compound being formed on the area of the substrate not attached with the sensor chip and then cured so as to form a dam structure for efficiently holding the sensor chip.

14. The semiconductor device of claim 11, wherein the adhesive layer is not in contact with the bonding wires.

15. The semiconductor device of claim 11, wherein the adhesive layer is made of a UV-curable adhesive.

16. A semiconductor device, comprising:
a substrate;
a sensor chip attached to the substrate, wherein the planar size of the sensor chip is smaller than that of the substrate, and the sensor chip has an active surface with a sensor area and a non-active surface opposite the active surface, the sensor chip being attached to the substrate through its non-active surface;
a plurality of bonding wires for electrically connecting the sensor chip to the substrate;
a first insulating layer covering the area of the substrate not attached with the sensor chip, wherein the height of the first insulating layer is not greater than the thickness of the sensor chip;
a second insulating layer disposed on the first insulating layer, the height of the second insulating layer being greater than the highest loop-height of the bonding wires;
an adhesive layer formed on the second insulating layer; and
a light transmitting cover adhered to the adhesive layer and covering the sensor chip.

17. The semiconductor device of claim 16, wherein the non-active surface of the sensor chip is thinned.

18. The semiconductor device of claim 16, wherein the insulating layer is made of resin compound, the resin compound being formed on the area of the substrate not attached with the sensor chip and then cured so as to form a dam structure for efficiently holding the sensor chip.

19. The semiconductor device of claim 16, wherein the adhesive layer is not in contact with the bonding wires.

20. The semiconductor device of claim 16, wherein the adhesive layer is made of a UV-curable adhesive.

21. The semiconductor device of claim 16, wherein the second insulating layer is made to cover the bonding wires or detach from the bonding wires.
